(19) United States
(12) Patent Application Publication
(10) Pub. No.: US 2002/0108744 A1
(43) Pub. Date: Aug. 15, 2002

(54) Heat sink assembly for non-planar integrated circuit package

(76) Inventors: John K. Bowman, Brighton, MA (US); Richard E. Olson, Rindge, NH (US)

Correspondence Address: CESARI AND MCKENNA, LLP, 88 BLACK FALCON AVENUE, BOSTON, MA, 02210, US

(21) Appl. No.: 10/126,734

(22) Filed: Apr. 19, 2002

Related U.S. Application Data
(63) Continuation of application No. 09/811,041, filed on Mar. 16, 2001.
(60) Provisional application No. 60/208,255, filed on May 31, 2000.

(51) Int. Cl. H05K 7/20

(52) U.S. Cl. 165/185; 361/705

(57) ABSTRACT

A heatsink assembly includes a rigid thermally conductive block having a relatively flat unobstructed surface area and a plurality of legs extending beyond and straddling that surface area, and a thermally conductive compliant pad positioned against the surface area. The assembly is adapted to be positioned over a chip package on a circuit board so that the block covers the package and the pad deforms initially to conform to the abutting surface of the package to establish intimate thermal contact between the package and the block. Suitable fasteners secure the block to the circuit board.

### RELATED APPLICATIONS

This application is a continuation of Ser. No. 09/811,041, filed 03/16/2001, now ______, which claims the benefit of Provisional Application No. 60/208,255, filed May 31, 2000.

### BACKGROUND OF THE INVENTION

1. Field of the Invention

This invention relates to integrated circuit packages. It relates more particularly to an improved heat sink assembly for an integrated circuit package which optimizes heat dissipation from the package despite package dimensional irregularities.

2. Background Information

Integrated circuit or chip packages including ball grid arrays, pin grid arrays, plastic quad flat packages, etc. are generally selected for their electrical characteristics, availability and cost and not necessarily for their mechanical or thermal attributes. At the time a particular package is selected, the electrical power consumption and heat dissipation from the chips mounted or housed in these packages can be estimated, but these estimates are often inaccurate. The power consumption is difficult to determine early in a product design cycle because the functionality of the chip generally evolves as the product design evolves. This evolution often results in an increase in functionality and an increase in dissipated electrical power from the chip and therefore from the package. This power must be transferred, in the form of heat, from the various transistor junctions on the chip housed in the package to a coolant medium, often, but not limited to, a stream of air moved past the package by means of a fan or blower.

The rate of heat transfer from the package has to equal the rate of power dissipation to prevent overheating of the package. This rate of heat transfer is equal to the product of the package surface area, the heat transfer coefficient and the mean package-to-coolant temperature difference. The magnitude of the temperature difference has an upper boundary since the junction temperature has an upper boundary. On the other hand, the heat transfer coefficient will depend upon the coolant velocity, but it is not a strong function thereof. Thus, in general, at some package power level, the surface area available for heat transfer must be increased to prevent overheating of the chip.

For a chip package having a low power dissipation, the surface area of the package may be adequate to dissipate that heat with an acceptable temperature difference. However at higher power dissipations, the package surface area is no longer adequate and must be augmented or increased by adding a heatsink in order to keep the junction-to-coolant temperature rise to an acceptable level. Heatsinks are manufactured in many shapes and forms, but they all have the characteristic of providing a large increase in surface area on the chip assembly which is exposed to the coolant medium. Usually such heatsinks include a base which contacts the chip package and fins extending from the base to provide the increased surface area.

The addition of a heatsink to a chip package is not the only attribute necessary to improve the heat transfer from the package. If the heatsink is not in good thermal contact with the package, its presence can actually increase the overall junction-to-coolant temperature difference. Thus, another required attribute of a chip package/heatsink assembly is to maintain a low thermal resistance between the package and the associated heatsink. Chip packages most often have a flat top surface. Therefore, a thermally efficient interface face can be effected by placing one of a number of commercially available interface materials between the heatsink and the associated package top surface and providing some fastening means such as an adhesive, mechanical clips, screws or the like to hold the surfaces together.

However, that mode of attachment is not effective if the chip package has an irregularly shaped or nonflat top surface and/or an ill-defined package height. The usual method of attaching a heatsink to a chip package cannot be utilized if the chip package surface to which the heatsink is to be adhered or attached is not flat or regular and the package has no underside clearances to allow for a clip attachment. Nor can the usual heatsink attachment be used with a chip package having a so-called “blob top” covering, i.e. one formed by a liquid encapsulant deposited on top of the package and allowed to harden in a shape defined by encapsulant's viscosity and surface tension. Such a blob top package not only has an irregular surface, but also the package height may vary from unit to unit.

Thus, there is a need in the industry to provide an effective means for attaching a heatsink to a chip package having a nonflat or irregular surface and/or an ill-defined package height.

### SUMMARY OF THE INVENTION

Accordingly, it is an object of the present invention to provide an integrated circuit or chip package and heatsink assembly which optimizes heat dissipation from the package or chip.

A further object of the invention is to provide a heatsink assembly which conducts heat efficiently and effectively from an associated integrated circuit or chip package.

Another object of the invention is to provide such an assembly which optimizes thermal transfer between a chip package and a heatsink in contact with the package.

Yet another object of the invention is to provide improved means for attaching a heatsink to an integrated circuit package having an irregular top surface and/or a variable package height.

Other objects will, in part, be obvious and will, in part, appear hereinafter. The invention accordingly comprises the features of construction, combination of elements and arrangement of parts which will be exemplified in the following detailed description, and the scope of the invention will be indicated in the claims.

Briefly, the heatsink assembly comprises a rigid thermally conductive heatsink body with a flat unobstructed undersurface area and a plurality of legs which straddle said area. Positioned against that undersurface area is a compliant, thermally conductive pad. When the heatsink assembly is positioned over an integrated circuit or chip package mounted to a circuit board, the compliant pad deforms as necessary to conform to the top of the chip package. This assures intimate thermal contact between the chip package and the heatsink body despite dimensional variations in the chip package. The heatsink assembly may be secured to the circuit board by suitable fasteners.

### BRIEF DESCRIPTION OF THE DRAWINGS

For a fuller understanding of the nature and objects of the invention, reference should be made to the following detailed description taken in connection with the accompanying drawings, in which:

FIG. 1 is an exploded fragmentary perspective view of a heatsink assembly incorporating the invention juxtaposed opposite an integrated circuit package, and

FIG. 2 is a sectional view taken along line 2-2 of FIG. 1 showing the heatsink assembly after its installation over the package.

### DESCRIPTION OF THE PREFERRED EMBODIMENT

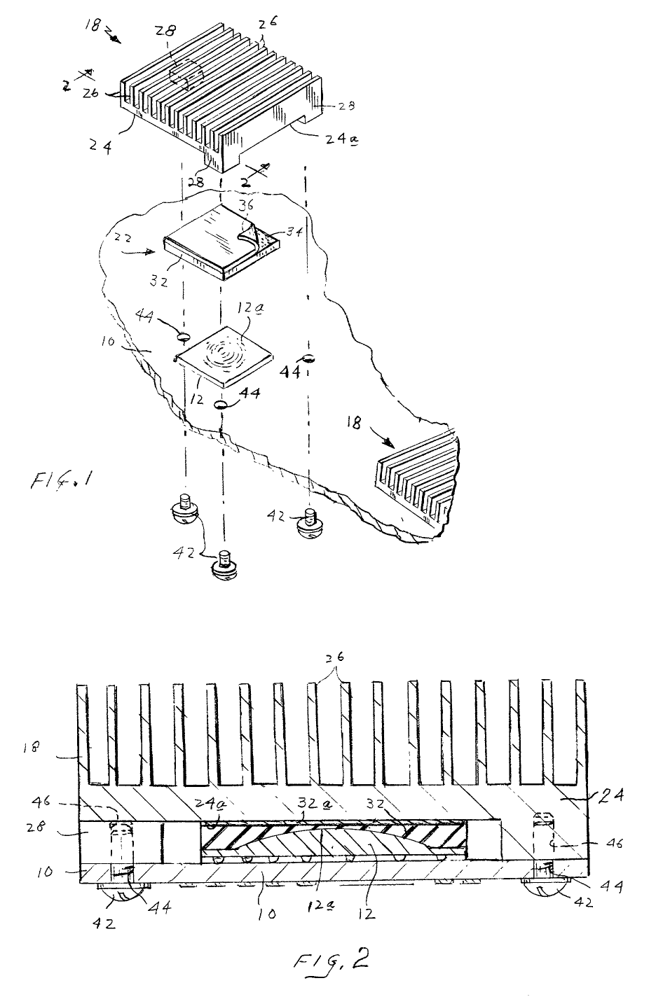

FIG. 1 of the drawings shows a portion of a printed circuit or wiring board 10 supporting one or more integrated circuit or chip packages 12 connected electrically and mechanically in the usual way to contact pads on board 10. The package 12 may be any one of a wide variety of conventional packages such as a ball grid array, pin grid array, land grid array, etc. Due to the process of electrically connecting the contacts of package is 12 to the contact pads on board 10, the spacing of package 12 from board 10 may vary from package to package within a limited range. Also, the illustrated chip package 12 is a so-called blob top package so that its top surface 12a has an irregular shape as shown in FIGS. 1 and 2. In sum, the height of package 12 above board 10 is ill-defined.

To efficiently and effectively conduct heat from package 12 despite its irregular geometry, a special heatsink assembly is employed comprising a highly compliant, thermally conductive heatsink shown generally at 18 and a highly thermally compliant conductive pad shown generally at 22. The heatsink has a generally rectangular base 24 whose length and width dimensions are somewhat larger than those of package 12. A multiplicity of the spaced-apart parallel fins 26 extend up from base 24 and a plurality of legs 28 extend down from the base. The illustrated heatsink has three such legs 28 which are more or less rectangular. Two of the legs are locate at the comers of the base on one side thereof. A third leg is located midway between the comers of the base at the opposite side of the base. Of course, it is also possible to have legs at all four comers of the base or two wider legs at opposite sides of the base. The point is to arrange the legs so that they support the base in a stable condition when the heatsink is placed on a more or less flat surface, while providing base 24 with a relatively flat unobstructed undersurface area 24a between the legs. Preferably, the free ends of legs 28 define a plane which is spaced parallel to surface area 24a. Preferably also, the dimensions of that undersurface 24a should be larger than the corresponding dimensions of chip package 12. Heatsink 18 may be made of any suitable rigid conductive material such as aluminum or copper.

The other main component of the heatsink assembly, namely pad 22, should have more or less the same length and width dimensions as those of package 12. In other words, pad 22 is somewhat smaller than the undersurface area 24a of heatsink 18.

The illustrated pad 22 comprises a relatively soft, compliant, elastomeric body 32 which is loaded with thermally conductive particles 33 (FIG. 2) to increase the thermal conductivity of the body and enhance its heat transfer capabilities. Suitable materials for body 32 are available from Chomerics, which is a division of SEAL Group of the Parker Hannifin Corporation and marketed under that company's trademark THERM-A-GAP. Those materials include aluminum oxide-filled silicone filler material and ceramic-filled silicone filler material and the pads are provided in a variety of thickness, thermal impedances and with a smooth or ribbed surface. Preferably, the elastomeric body 32 is formed with a backing strip 32a, e.g., aluminum foil, fiberglass or the like and the backing may be coated with an adhesive 34 with the adhesive, in turn, being protected by a peel-away cover strip 36. After peeling away the strip 36, the pad 22 may be centered on and adhered to the undersurface area 24a of heatsink 18 to facilitate installation of the heatsink assembly.

The term “filler material” refers generally to aluminum oxide or ceramic materials. This filler material is added to a matrix which may be formed from a silicone material. Those skilled in the art will recognize that alternative materials may be used.

In order to install the heatsink assembly to board 10, pad 22 is adhered to the underside of heatsink 18 as aforesaid. Then, the heatsink assembly is positioned against board 10 so that pad 22 is centered on package 12 as shown in FIG. 2. In other words, the legs 28 of the heatsink 18 bracket or straddle package 12. Because the pad 32 is highly compliant, when the heatsink is pressed down against board 10, the pad will deform initially as necessary to conform to the irregular surface 12a of package 12. This assures that pad 32 and the heatsink base 24 will be in intimate thermal contact via pad 22 over the entire area of the package top surface 12a thereby optimizing transmission of heat from the package to the heatsink 18. Due to the presence of pad 22, the heatsink assembly can also accommodate some variation in the height of package 12 above board 10 due to its irregular shape as well as due to the tolerances inherent in the connections between package 12 and board 10. Thus, intimate thermal contact between the heatsink and the chip package is assured from unit to unit as the various chip packages are assembled to board 10.

The heatsink assembly may be secured to board 10 by threaded fasteners 42 extending up through clearance holes 44 in board 10 and turned down into threaded holes 46 formed in the ends of the heatsink legs 28 as shown in FIG. 2. Thus, when the heatsink assembly is attached to board 10, it completely covers and protects chip package 12. It also establishes a path for efficient transfer of heat from package 12 to heatsink 18 and thence to the air stream circulating past board 10. In this connection, the length of legs 28 along with the height of package 12 and the thickness of the compliant pad 22 establish the initial compression of the pad and thus the functionality of the pad to remove heat from the package. In other words, to establish the compression, the lengths of legs 28 are less than the combined thickness of chip package 12 and pad 22.

Note also that a heatsink 18 with three legs 28 as shown has a preferred orientation on circuit board 10 in that the legs must align with the fastener holes 44 therein. This precludes installing the heatsink with the fins 26 oriented in the wrong direction.

It will thus be seen that the objects set forth above, among those made apparent from the preceding description, are efficiently attained. Also, since certain changes may be made in the above construction without departing from the scope of the invention, it is intended that all matter contained in the above description or shown in the accompanying drawings shall be interpreted as illustrative and not in a limiting sense.

It is also to be understood that the following claims are intended to cover all of the generic and specific features of the invention described herein.

What is claimed is:

1. A heatsink assembly comprising
a rigid thermally conductive block having a relatively flat unobstructed surface area and a plurality of legs extending beyond and straddling said surface area, said legs having free ends which lie in a common plane spaced substantially parallel to said surface area;
a thermally conductive compliant pad positioned against said surface area;
a printed circuit board;
a chip package mounted to the circuit board, said block being positioned on said circuit board so that said pad engages a surface of said chip package, said chip package and pad having a predetermined combined thickness, and
clamping means including fasteners for fastening the free ends of said block legs to said circuit board so that the block covers the chip package, said legs having a length less than said combined thickness so that the pad is initially compressed sufficiently to establish a highly thermally conductive path between said surface and the block over the entire area of said surface.

2. The assembly defined in claim 1 wherein said pad comprises
a body of compliant filler material, and
a multiplicity of thermally conductive particles distributed throughout said body.

3. The assembly defined in claim 2 further comprising an adhesive layer between the pad and the surface for adhering the pad to said surface area.

4. The assembly defined in claim 2 wherein said body has a flat surface covered by a backing strip.

5. The assembly defined in claim 4 and further including an adhesive material coating said backing strip for adhering the pad to said surface area.

6. The assembly defined in claim 1 wherein the block has aligned first and second legs at one side of said surface area and a third leg offset from the first and second legs at the opposite side of the surface area.

7. The assembly defined in claim 7 wherein the block includes a multiplicity of spaced-apart parallel fins extending from the block in a direction away from said legs.

8. The assembly defined in claim 1 wherein the block has aligned first and second legs at one side of said surface area and a third leg offset from the first and second legs at the opposite side of said surface area whereby the block has a preferred orientation on the circuit board.
